(19) United States
(12) Patent Application Publication
(10) Pub. No.: US 2026/0065024 A1
(43) Pub. Date: Mar. 5, 2026

(54) DESIGN METHOD FOR SEMICONDUCTOR PARAMETERS AND ELECTRONIC DEVICE

(71) Applicant: Hon Hai Precision Industry Co., Ltd., New Taipei City (TW)

(72) Inventors: Yi-Rong Lin, New Taipei City (TW); Nien-Yi Jan, New Taipei City (TW); Yung-Hui Li, New Taipei City (TW); Tejender Singh Rawat, New Taipei City (TW); Wei-Cheng YU, New Taipei City (TW); Yi-Kai HSIAO, New Taipei City (TW); Chia-Lung HUNG, New Taipei City (TW); Hao-Chung KUO, New Taipei City (TW)

(73) Assignee: Hon Hai Precision Industry Co., Ltd., New Taipei City (TW)

(21) Appl. No.: 19/315,821

(22) Filed: Sep. 1, 2025

Related U.S. Application Data
(60) Provisional application No. 63/690,318, filed on Sep. 4, 2024.

(51) Int. Cl. G06N 3/0455; G06F 30/32

(52) U.S. Cl. CPC G06N 3/0455; G06F 30/32

(57) ABSTRACT

Disclosed are a design method for semiconductor parameters and an electronic device. The design method for the semiconductor parameters includes: inputting a conditional parameter to a decoder of a conditional variational autoencoder (CVAE) model to generate a predicted design parameter; inputting the predicted design parameter to an encoder of the CVAE model to generate a predicted conditional parameter corresponding to the predicted design parameter; and calibrating the predicted design parameter according to the predicted conditional parameter and the conditional parameter to generate an output design parameter.

### CROSS-REFERENCE TO RELATED APPLICATION

This application claims the priority benefit of U.S. provisional application Ser. No. 63/690,318, filed on Sep. 4, 2024. The entirety of the above-mentioned patent application is hereby incorporated by reference herein and made a part of this specification.

### BACKGROUND

### Technical Field

The present disclosure relates to a method and a device, and particularly relates to a design method and an electronic device.

### Description of Related Art

Conventional design of semiconductor device relies on technology computer aided design (TCAD) software to a large extent for simulation and verification. However, the computational demands of TCAD software takes a significant amount of time and requires a lot of resources. In each adjustment of the design parameters of a semiconductor device, it is required to perform multiple verification processes, which substantially affects the design and production efficiency of the semiconductor.

### SUMMARY

The present disclosure provides a design method and an electronic device, which may effectively improve the design efficiency of semiconductor devices.

The design method for semiconductor parameters of the present disclosure includes: inputting a conditional parameter to a decoder of a conditional variational autoencoder (CVAE) model to generate a predicted design parameter; inputting the predicted design parameter to an encoder of the CVAE model to generate a predicted conditional parameter corresponding to the predicted design parameter; and calibrating the predicted design parameter according to the predicted conditional parameter and the conditional parameter to generate an output design parameter.

The electronic device of the present disclosure includes a memory and a processor. The memory stores an instruction. The processor is coupled to the memory for accessing and executing the following steps according to the instruction: inputting a conditional parameter to a decoder of a conditional variational autoencoder (CVAE) model to generate a predicted design parameter; inputting the predicted design parameter to an encoder of the CVAE model to generate a predicted conditional parameter corresponding to the predicted design parameter; and calibrating the predicted design parameter according to the predicted conditional parameter and the conditional parameter to generate an output design parameter.

Based on the above, the design method and the electronic device of the present disclosure may verify whether the predicted design parameter conform to the set conditional parameter, and calibrate the predicted design parameter accordingly, thereby effectively improving the design efficiency of semiconductor devices.

### BRIEF DESCRIPTION OF THE DRAWINGS

FIG. 1 is a flowchart of a design method for semiconductor parameters according to an embodiment of the present disclosure.

FIG. 2 is a schematic view of an architecture of a conditional variational autoencoder model according to an embodiment of the present disclosure.

FIG. 3 is a flowchart of a training method according to an embodiment of the present disclosure.

FIG. 4 is a block diagram of an electronic device according to an embodiment of the present disclosure.

### DESCRIPTION OF THE EMBODIMENTS

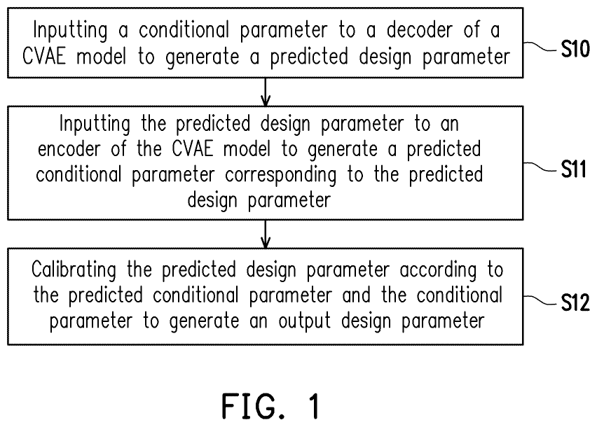

FIG. 1 is a flowchart of a design method for semiconductor parameters according to an embodiment of the present disclosure. A conditional variational autoencoder (CVAE) model may be applicable for the design method of FIG. 1. Generally speaking, the design method of FIG. 1 may generate design parameter values in circuits while taking conditional parameters into consideration, thus enabling the overall circuit design to adaptively perform prediction according to set conditional parameters, thereby generating output design parameters that satisfy corresponding conditions.

The design method of FIG. 1 includes steps S10˜S12. In step S10, a conditional parameter is input into a decoder of the CVAE model, enabling the decoder to perform a prediction according to the conditional parameter and generate a predicted design parameter. Ideally, in a trained CVAE model, the predicted design parameter generated by the decoder will conform to the constraints of the conditional parameter. However, in some cases, the predicted design parameters generated by the decoder may not yet meet the requirements of the conditional parameter. In this case, the design method may verify and adjust the predicted design parameter in subsequent steps S11 and S12.

In step S11, the predicted design parameter generated by the decoder is input into an encoder of the CVAE model to generate a predicted conditional parameter corresponding to the predicted design parameter. In this embodiment, in the CVAE model applied by the design method, the architecture of the encoder is trained to enable the encoder to receive the predicted design parameter and generate the corresponding predicted conditional parameter. In this way, the design method may evaluate whether the generated predicted conditional parameter conforms to the input conditional parameter in subsequent step S12, and perform corresponding calibration on the predicted design parameter accordingly.

In step S12, the predicted design parameter is calibrated according to the predicted conditional parameter and the conditional parameter to generate an output design parameter. Generally speaking, the calibration of the predicted design parameter may be restored according to a gradient thereof. Specifically, the calibration on the predicted design parameter may be performed by calculating a difference between the conditional parameter and the predicted conditional parameter first. Then the difference between the conditional parameter and the predicted conditional parameter is multiplied by the gradient of the predicted design parameter to calculate a product of the two. Finally, the product is added to the predicted design parameter to calibrate the predicted design parameter, thereby generating a calibrated output design parameter. In some embodiments, the calibrated output design parameter may be utilized to manufacture a corresponding semiconductor device.

Generally speaking, the CVAE model adopted in the design method of FIG. 1 is derived from an extended architecture of a variational autoencoder (VAE), with the main difference being that the CVAE model introduces conditional variables in a generative model. The target of the VAE model is to learn a generative model, enabling the VAE model to generate data by sampling from a latent space. The CVAE model further adds the conditional variables on this basis, enabling the CVAE model to generate a corresponding predicted result according to different conditional situations when generating data. Generally speaking, the CVAE model has an encoder and a decoder that correspond to each other. The target of the encoder is to map input data (such as images, text, etc.) to the latent space, and the target of the decoder is to generate predicted data according to the sampling result in the latent space and the input conditional variables. The encoder and the decoder have hidden layers for extracting and identifying features. Specifically, the encoder and the decoder store weights to represent a mathematical relationship among the conditional parameter, the predicted design parameter, and the predicted conditional parameter.

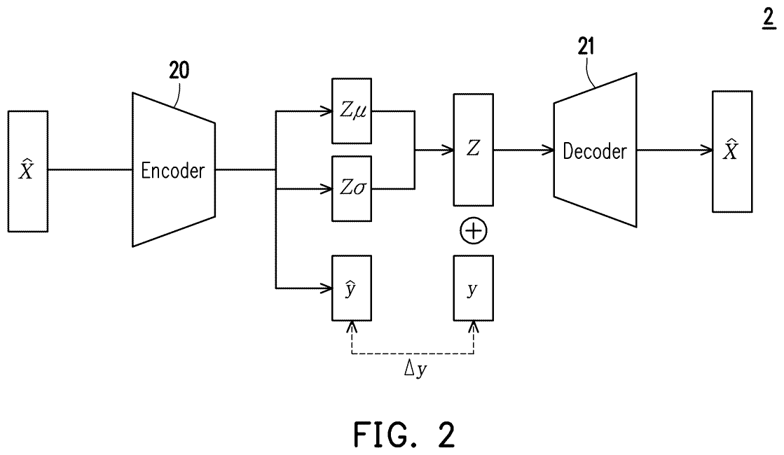

FIG. 2 is a schematic view of an architecture of a CVAE model 2 according to an embodiment of the present disclosure. The CVAE model 2 of FIG. 2 includes an encoder 20 and a decoder 21. The following will explain the process of generating output design parameters in the design method of FIG. 1 together with FIG. 1 and FIG. 2.

In step S10, a conditional parameter y is provided to the decoder 21 of the CVAE model 2. Specifically, a sampling vector Z is also input into the decoder 21 together with the conditional parameter y, and the sampling vector Z may be obtained by random sampling from a normal distribution (which may be represented by mean and standard deviation). The decoder 21 may perform inference according to the received sampling vector Z and the conditional parameter y, thereby generating a predicted design parameter \hat{X} corresponding to conditional parameter y.

In step S11, the predicted design parameter \hat{X} is input to the encoder 20 of the CVAE model 2. The trained encoder 20 may generate a predicted conditional parameter ŷ corresponding to the predicted design parameter \hat{X} according to the predicted design parameter \hat{X}. As shown in FIG. 2, the encoder 20 further generates a distribution model of the predicted design parameter \hat{X} in addition to the generating the predicted conditional parameter ŷ. In some embodiments, the predicted design parameter \hat{X} may have a normal distribution and may be represented by a distribution mean Zμ and a distribution standard deviation Zσ. Additionally, the mean and the standard deviation generated by the encoder with respect to the design parameter \hat{X} are only used during training and are not used during inference.

Finally, in step S12, a difference between the conditional parameter y and the predicted conditional parameter ŷ may be calculated as shown in Equation (1).

$$Δ y = y - \hat{y} \qquad ( 1 )$$

Wherein Δy is the difference between the conditional parameter y and the predicted conditional parameter ŷ. Next, the difference Δy between the conditional parameter y and the predicted conditional parameter ŷ may be multiplied by a gradient of the predicted conditional parameter \hat{X}, and a product obtained from the above multiplication may be added to the predicted design parameter \hat{X} to generate the output design parameter.

First, it is defined that:

$$L = y - \hat{y} . \qquad ( 1 )$$

(2). ŷ=f(\hat{X}), wherein f(⋅) is an encoder equation.
(3). Assume \hat{X} has two features (for example, \hat{X}=(a,b));

Step 1: Calculating

$$\frac{\partial L}{\partial \hat{X}}$$

$$\frac{\partial L}{\partial \hat{X}} = ( \frac{\partial L}{\partial a} , \frac{\partial L}{\partial b} ) = ( \frac{\partial L}{\partial f} \frac{\partial f}{\partial a} , \frac{\partial L}{\partial f} \frac{\partial f}{\partial b} ) , wherein \frac{\partial f}{\partial a} and \frac{\partial f}{\partial b}$$

may be derived by substituting into a weight calculation of the encoder.

Step 2: Calculating Xout

$$Xout = \hat{X} + λ \frac{\partial L}{\partial \hat{X}} = ( a + λ \frac{\partial L}{\partial f} \frac{\partial f}{\partial a} , b + λ \frac{\partial L}{\partial f} \frac{\partial f}{\partial b} ) ,$$

wherein λ may be used to adjust a moving distance toward a direction of the gradient; if the moving distance is set too large, the outcome might actually be worse.

Wherein Xout is an output design parameter.

In some embodiments, the design method may be applied to a process of designing and manufacturing semiconductor devices with guard rings. To ensure that the designed and manufactured semiconductor device has a specific voltage withstand capability, the conditional parameter of the semiconductor device may include, for example, a breakdown voltage. The adjustable design parameter of the semiconductor device may include, but are not limited to, the number of guard rings, implantation dose, implantation energy, or other similar design parameters. During the process of manufacturing semiconductor devices, the aforementioned or other design parameters will influence the breakdown voltage of the semiconductor device to some extent.

TABLE 1

| | Predicted design parameter \hat{X} | | | Predicted | Simulation |
|---|---|---|---|---|---|
| Conditional | Number of | Implantation | Implantation | conditional | software |
| parameter y | guard rings | dose | energy | parameter ŷ | verification y |
| 2710.2 | 12.83 | 3.6100868e+14 | 375.07077 | 2644.1624 | 2689.0 |
| | | | 549.87567 | | 2725.855 |
| | | | (+174.8) | | |

Table 1 lists the value of the conditional parameter y, the predicted design parameter \hat{X}, the predicted conditional parameter ŷ, and the output design parameter Xout. Specifically, the conditional parameter y may be set to 2710.2 volts, and the predicted design parameter \hat{X} generated by the decoder 21 according to the conditional parameter y may include guard rings in a quantity of 12.83, an implantation dose of 3.6100868e+14, and an implantation energy of 375.07077. The predicted conditional parameter ŷ calculated by the encoder 20 according to the predicted design parameter \hat{X} is 2644.1624 volts.

It may be observed that since the predicted conditional parameter ŷ corresponding to the predicted design parameter \hat{X} is less than the predicted conditional parameter ŷ, it means that the semiconductor device manufactured by the predicted design parameter \hat{X} does not satisfy the voltage withstand capability required by the conditional parameter y. In this situation, the design method may further multiply the difference between the predicted conditional parameter ŷ and the conditional parameter y by the gradient ∇x of the predicted design parameter \hat{X} according to the difference between the predicted conditional parameter ŷ and the conditional parameter y.

The decoder will first recommend a design parameter according to the value of the conditional parameter 2710.2, the value of y predicted by the encoder is 2644.1624, and the calculation result obtained by utilizing TCAD is 2689.0, both of the values are not close to the target 2710.2. Therefore, we intend to utilize the encoder to calculate the gradient of each feature with respect to the target. By making slight adjustments in the direction of the gradient, the aim is to adjust the design parameter such that the resulting BV is closer to 2710.2.

Therefore, it is necessary to calculate the partial derivatives of the condition and the y predicted by the encoder with respect to each of the three features:

$$L = 2710.2 - 2644.1624 ;$$

$$\frac{\partial L}{\partial \hat{X}} = ( \frac{\partial L}{number of guard rings \partial } , \frac{\partial L}{dose \partial } , \frac{\partial L}{energy \partial } )$$

Fine-tuned design parameter:

$$Xout = \hat{X} + λ \frac{\partial L}{\partial \hat{X}} = ( 12.83 + λ \frac{\partial L}{number of guard rings \partial } , \\ 3.6100868 e + 14 + λ \frac{\partial L}{dose \partial } , 375.07077 + λ \frac{\partial L}{energy \partial } )$$

In this embodiment, the design method may only perform calibration on the implantation energy (that is, the item [symbol] ) in the predicted design parameter, as long as the λ used for the other three features are (0,0,1) respectively. Therefore, the implantation energy may be calibrated to 549.87567, and the other parameters in the predicted design parameter \hat{X} maintain unchanged. That is to say, in the finally calculated output design parameter Xout, the values of the number of guard rings, implantation dose, and implantation energy are 12.83, 3.6100868e+14, and 549.87567, respectively.

In some embodiments, although not explicitly stated in Table 1, by utilizing the technology computer aided design (TCAD) software to verify the output design parameter Xout, it can be obtained that the breakdown voltage of output design parameter Xout can withstand up to 2725.855 volts, proving the reliability of the output design parameter generated by the design method. Additionally, in other embodiments, the calibrated output design parameter Xout may also be input again into the encoder 20 of the CVAE model 2 to enable the encoder 20 to determine the predicted conditional parameter corresponding to the output design parameter Xout. The benefit of inputting the output design parameter Xout into the encoder 20 again is that the encoder 20 generating the predicted conditional parameter and performing calibration to generate the output design parameter Xout may be executed automatically as a loop until the predicted conditional parameter generated by the encoder 20 satisfies the set conditional parameter.

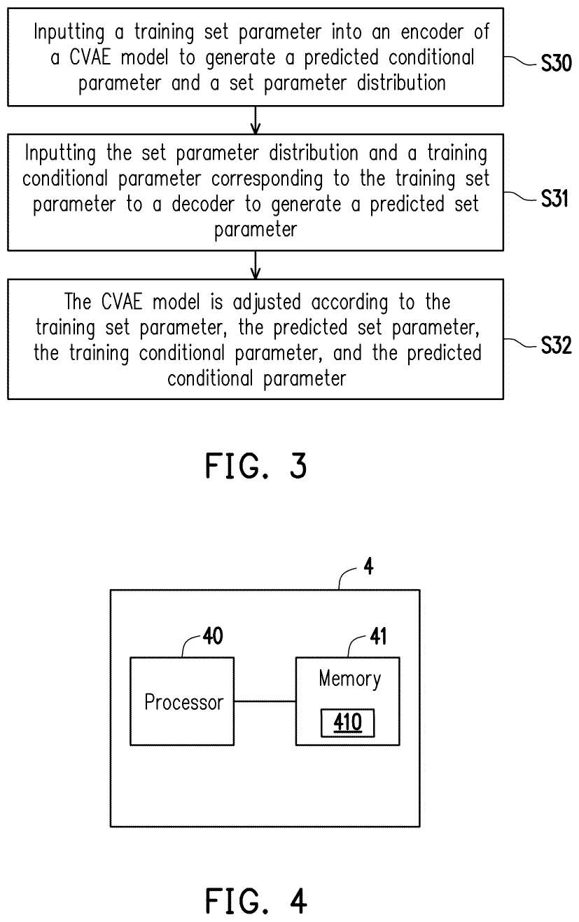

FIG. 3 is a flow chart of a training method of an embodiment of the present disclosure. The training method in FIG. 3 may be used to train the CVAE model 2 of FIG. 2, for example. The training method includes steps S30˜S32. Next, please refer to FIG. 2 and FIG. 3 together for comprehension of the training process of the CVAE model 2.

In step S30, a training set parameter and a training conditional parameter may first be obtained. The training set parameter and the training conditional parameter are, for example, obtained after simulation verification by the TCAD software. The training set parameter may include a design parameter of the semiconductor device to be designed, and the training conditional parameter may include operating conditions satisfied by the semiconductor device designed and manufactured with the training set parameter. Next, the training set parameter may first be provided to the encoder 20 of the CVAE model 2, so that the encoder 20 generates the predicted conditional parameter and a model distribution (represented by mean and standard deviation) corresponding to a set parameter.

In step S31, the set parameter obtained by sampling the set parameter distribution and the training conditional parameter corresponding to the training set parameter may be input into decoder 21 to generate a predicted set parameter. In this step, to ensure that the input data is verified, the parameter input into the decoder 21 is a verified training conditional parameter, so that the decoder 21 generates the predicted set parameter accordingly.

In step S32, the CVAE model 2 is adjusted according to the training set parameter, the predicted set parameter, the training conditional parameter, and the predicted conditional parameter. Specifically, the training purpose of the CVAE model 2 is to enable the predicted conditional parameter and the predicted set parameter to be as closer to the training conditional parameter and the training set parameter as possible, respectively. Therefore, the CVAE model 2 will adjust the weights in the encoder 20 and the decoder 21 according to the loss, so that the generated predicted result gradually converges toward a training set. The loss mentioned here, in addition to a difference between the predicted conditional parameter and the training conditional parameter, also includes that a distribution mapped by the encoder should be similar to a normal distribution, therefore the overall loss will be calculated in conjunction with the normal Gaussian distribution.

FIG. 4 is a block diagram of an electronic device 4 of an embodiment of the present disclosure. The electronic device 4 may, for example, store the CVAE model 2 illustrated in FIG. 2, and be used to execute the design method of FIG. 1 and/or the training method of FIG. 3.

As shown in FIG. 4, the electronic device 4 includes a processor 40 and a memory 41. The memory 41 stores an instruction 410. The processor 40 is coupled to the memory 41 for accessing and executing the following steps according to the instruction 410: inputting the conditional parameter to the decoder of the conditional variational autoencoder (CVAE) model to generate the predicted design parameter; inputting the predicted design parameter to the encoder of the CVAE model to generate the predicted conditional parameter corresponding to the predicted design parameter; and calibrating the predicted design parameter according to the predicted conditional parameter and the conditional parameter to generate the output design parameter.

In some embodiments, the processor 40 may be, for example, a central processing unit (CPU), or other programmable general-purpose or special-purpose micro control unit (MCU), a microprocessor, a digital signal processor (DSP), a programmable controller, an application specific integrated circuit (ASIC), a graphics processing unit (GPU), a neural processing unit (NPU), an arithmetic logic unit (ALU), a complex programmable logic device (CPLD), a field programmable gate array (FPGA), any other kind of integrated circuit, a state machine, an advanced RISC machine (ARM)-based processor, or other similar elements or combinations of the above elements.

In some embodiments, the memory 41 may be, for example, any type of fixed or removable random access memory (RAM), read-only memory (ROM), flash memory, hard disk drive (HDD), solid state drive (SSD) or similar elements or combinations of the above elements, for storing the instruction 410, multiple modules or various application programs that can be executed by the processor 40.

Additionally, the processor 40 in the electronic device 4 may be formed by a single circuit unit or by multiple circuit units. In embodiments where the electronic device 4 has only one single processing unit, the processing unit may be applied to steps S10˜S11 of executing the CVAE model 2 in FIG. 1, and may also be used to execute step S12 of calibrating and generating the output design parameter. Additionally, in the case where the electronic device 4 is formed by multiple processing units, the processor 40 may, for example, include a first processing unit implemented with CPU and a second processing unit implemented with GPU. In FIG. 1, steps S10˜S11 regarding executing the CVAE model 2 may be assigned to the second processing unit for execution, while step S12 of calibrating and generating the output design parameter may be assigned to the first processing unit for execution.

In summary, the design method and the electronic device of the present disclosure may perform prediction through an improved CVAE model to generate predicted design parameters and corresponding predicted conditional parameters. Through verification of the predicted conditional parameters, the predicted design parameters may be correspondingly calibrated to generate output design parameters that conform to actual conditional parameter requirements, thereby effectively reducing the overall design complexity of semiconductor devices and improving the design and/or production efficiency of semiconductor devices.

What is claimed is:

1. A design method for semiconductor parameters, comprising:
inputting a conditional parameter to a decoder of a conditional variational autoencoder (CVAE) model to generate a predicted design parameter;
inputting the predicted design parameter to an encoder of the CVAE model to generate a predicted conditional parameter corresponding to the predicted design parameter; and
calibrating the predicted design parameter according to the predicted conditional parameter and the conditional parameter to generate an output design parameter.

2. The design method as described in claim 1, comprising calibrating the predicted design parameter according to a difference between the predicted conditional parameter and the conditional parameter.

3. The design method as described in claim 2, comprising calculating a product by multiplying the difference between the predicted conditional parameter and the conditional parameter by a gradient of the predicted design parameter, and then calculating the output design parameter by adding the product to the predicted design parameter.

4. The design method as described in claim 1, wherein the predicted design parameter comprises at least one of a number of guard rings, an implantation dose, and an implantation energy, and the conditional parameter comprises a breakdown voltage.

5. The design method as described in claim 1, wherein the decoder generates the predicted design parameter according to a sampling vector and the conditional parameter.

6. An electronic device, comprising:
a memory, storing an instruction;
a processor, coupled to the memory, the processor for accessing and executing the following steps according to the instruction:
inputting a conditional parameter to a decoder of a conditional variational autoencoder (CVAE) model to generate a predicted design parameter;
inputting the predicted design parameter to an encoder of the CVAE model to generate a predicted conditional parameter corresponding to the predicted design parameter; and
calibrating the predicted design parameter according to the predicted conditional parameter and the conditional parameter to generate an output design parameter.

7. The electronic device as described in claim 6, wherein the processor is configured for executing: calibrating the predicted design parameter according to a difference between the predicted conditional parameter and the conditional parameter.

8. The electronic device as described in claim 7, wherein the processor is configured for executing: calculating a product by multiplying the difference between the predicted conditional parameter and the conditional parameter by a gradient of the predicted design parameter, and then calculating the output design parameter by adding the product to the predicted design parameter.

9. The electronic device as described in claim 6, wherein the predicted design parameter comprises at least one of a number of guard rings, an implantation dose, and an implantation energy, and the conditional parameter comprises a breakdown voltage.

10. The electronic device as described in claim 6, wherein the decoder generates the predicted design parameter according to a sampling vector and the conditional parameter.
